(19) United States
(12) Patent Application Publication
(10) Pub. No.: US 2019/0252207 A1
(43) Pub. Date: Aug. 15, 2019

(54) SEMICONDUCTOR SUBSTRATE AND PROCESSING METHOD THEREOF

(71) Applicant: CHIPBOND TECHNOLOGY CORPORATION, Hsinchu (TW)

(72) Inventor: Chin-Tang Hsieh, Kaohsiung City (TW)

(21) Appl. No.: 15/960,707

(22) Filed: Apr. 24, 2018

(30) Foreign Application Priority Data
Feb. 14, 2018 (TW) 107105587

(51) Int. Cl. H01L 21/48; H01L 23/498; H01L 21/66

(52) U.S. Cl. CPC H01L 21/481; H01L 23/49838; H01L 23/145; H01L 23/4985; H01L 22/20

(57) ABSTRACT

A semiconductor substrate includes a carrier and leads formed on the carrier, and a space exists between the adjacent leads and reveals a surface of the carrier. A processing method of the semiconductor substrate uses a laser beam passing through the space to etch the carrier such that there are ditches recessed on the carrier. The ditches can increase fluidity of coating fluid, such as underfill, ACF and solder resist. Furthermore, during etching the carrier, the laser beam also can remove residues remained between the leads to improve yield of the semiconductor substrate.

### FIELD OF THE INVENTION

This invention relates to a semiconductor substrate and a processing method thereof. The semiconductor substrate is etched by using laser beams to form ditches on a surface of a carrier. The ditches are provided to increase fluidity of fluid and yield of the semiconductor substrate.

### BACKGROUND OF THE INVENTION

Semiconductor package technology develops with the evolution of consumer electronics, and super fine pitch leads will be essential in the future in order to satisfy the electronics requirement. However, fluid coated in package process, such as underfill or ACF, is difficult to flow between the super fine pitch leads, so the fluid can't distribute on substrate surface evenly. And the narrow pitch between the leads may cause residues located between the leads can't be removed fully during etching process. Otherwise, the leads may be damaged during removing the residues so that the yield of semiconductor package may not be improved significantly.

### SUMMARY

An object of the present invention is to provide a processing method for processing a semiconductor substrate. The semiconductor substrate includes a carrier and a plurality of leads formed on a surface of the carrier. A space exists between the adjacent leads and reveals the surface. In the processing method, a laser beam passing through the space is used to etch the carrier so that a plurality of ditches are recessed on the surface revealed by the space.

Another object of the present invention is to provide semiconductor substrate which includes a carrier and a plurality of leads. The carrier has a surface and a plurality of ditches, and the leads are formed on the surface of the carrier. A space exists between the adjacent leads and reveals the surface. The ditches are recessed on the surface revealed by the space and formed by using a laser beam passing through the space to etch the carrier.

The processing method of the present invention uses the laser beam to etch the carrier revealed by the leads such that the ditches are formed between the adjacent leads. The ditches can increase fluidity of fluids coated in following-up package procedures to increase yield of semiconductor package. Additionally, the processing method of the present invention can be used to process semiconductor substrates having super fine pitch leads because the processing method can precisely etch the carrier to protect the leads from damage.

### DESCRIPTION OF THE DRAWINGS

FIG. 1 is a perspective diagram illustrating a semiconductor substrate in accordance with one embodiment of the present invention.

FIG. 2 is a lateral view diagram illustrating the semiconductor substrate in accordance with one embodiment of the present invention.

FIG. 3 is a schematic diagram illustrating a processing method of the semiconductor substrate in accordance with one embodiment of the present invention.

FIG. 4 is a lateral view diagram illustrating the semiconductor substrate in accordance with one embodiment of the present invention.

FIG. 5 is a block diagram illustrating an automated optical inspection device in accordance with one embodiment of the present invention.

### DETAILED DESCRIPTION OF THE INVENTION

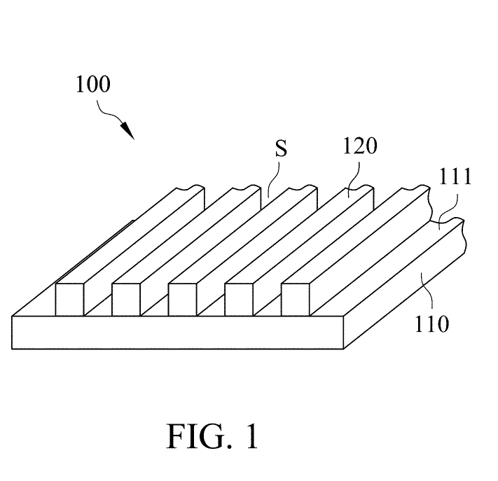

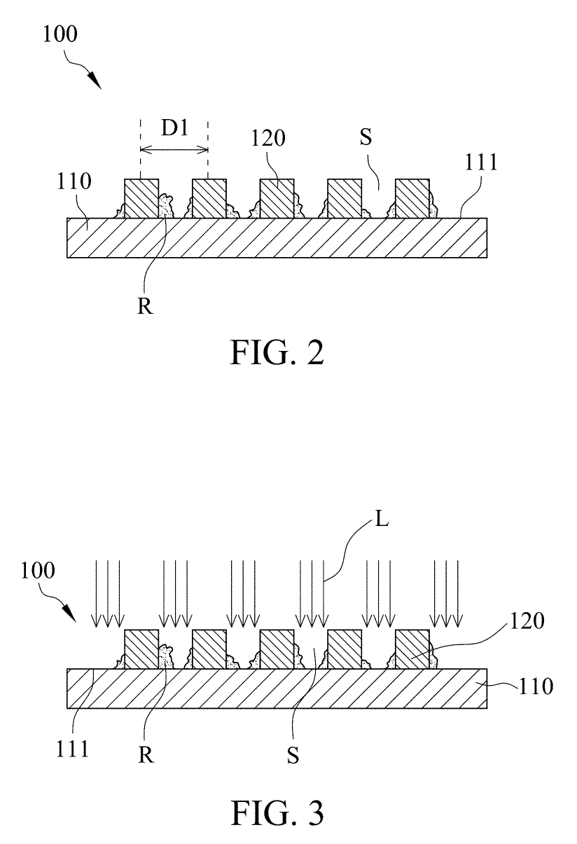

With reference to FIGS. 1 and 2, a processing method of the present invention is provided to process a semiconductor substrate 100. The semiconductor substrate 100 includes a carrier 110 and a plurality of leads 120 formed on a surface 111 of the carrier 110. There is a space S between the adjacent leads 120, and the space S reveals the surface 111 of the carrier 110. In this embodiment, the carrier 110 is made of polyimide (PI) and the leads 120 are made of copper (Cu). However, the carrier 110 can be made of other flexible polymer materials and the leads 120 can be made of other proper metals or alloys.

With reference to FIGS. 1 and 2, the leads 120 are formed on the carrier 110 by a patterning process. The patterning process includes the steps of: (i) forming a metal layer on the surface 111 of the carrier 110; (ii) forming a patterned photoresist on the metal layer; and (iii) etching the metal layer to form the leads 120 by using the patterned photoresist as a mask. A photoresist layer is patterned through an exposing and developing process to form the patterned photoresist. Preferably, a pitch D1 smaller than 20 μm exists between the adjacent leads 120.

With reference to FIG. 2, owing to the pitch D1 between the adjacent leads 120 is too narrow, some residues R, such as metal, photoresist or contaminates, may remain in the space S between the leads 120 after the patterning process. The residues S are difficult to remove and may lower the stability and yield of the semiconductor substrate 100.

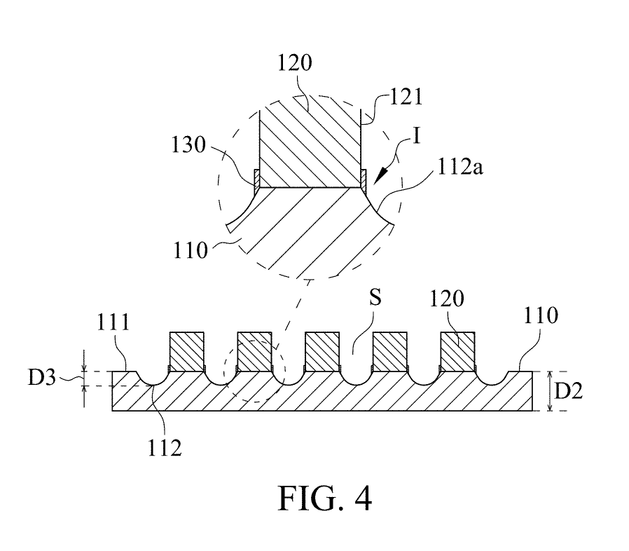

With reference to FIGS. 3 and 4, in the processing method of the present invention, a laser beam L passing through the space S is used to etch the carrier 110 such that a plurality of ditches 112 are recessed on the surface 111 of the carrier 110. The ditches 112 communicate with the space S and are provided to increase the fluidity of coating fluids applied in following-up processes because the coating fluids, such as underfill, anisotropic conductive film (ACF) and solder resist, can flow and distribute on the semiconductor substrate 100 evenly.

The laser beam L not only etch the carrier 110 but also remove the residues R in the space S, in other words, the present invention can process the semiconductor substrate 100 and remove the residues R at the same time by using a single procedure. So the yield of the semiconductor substrate 100 can be improved significantly.

With reference to FIG. 4, the carrier 110 before etching by the laser beam L has a thickness D2, and the ditches 112 have a depth D3 that is the shortest distance between the surface 111 and the bottom of the ditches 112. The depth D3 is smaller than or equal to one half of the thickness D2, the thickness D2 is between 20 and 40 μm and the depth D3 is between 0.1 and 15 μm. The depth D3 is preferably smaller than or equal to one third of the thickness D2. And substantially, the carrier 110 has the thickness D2 of 35 μm and the ditches 112 have the depth D3 of 10 μm in this embodiment.

With reference to FIG. 4, each of the leads 120 has a lateral surface 121 facing toward the space S, and each of the ditches 112 has a lateral wall 112a connecting with the lateral surface 121. There is a connecting interface I between the lateral surface 121 of each of the leads 120 and the lateral wall 112a of each of the ditches 112. When the carrier 110 is etched by the laser beam L, the carrier 110 is melted partially to generate a melted material because of the energy of the laser beam L. Furthermore, the melted material is sprayed and solidified on the connecting interface I to form a protection layer 130 during the laser beam L is moving in the space S. The protection layer 130 overlay on the connecting interface I and preferably also overlay on the lateral surface 121 of the leads 120 near the connecting interface I. The protection layer 130 can prevent migration phenomenon of the leads 120 such as ion migration, metal migration and electromigration.

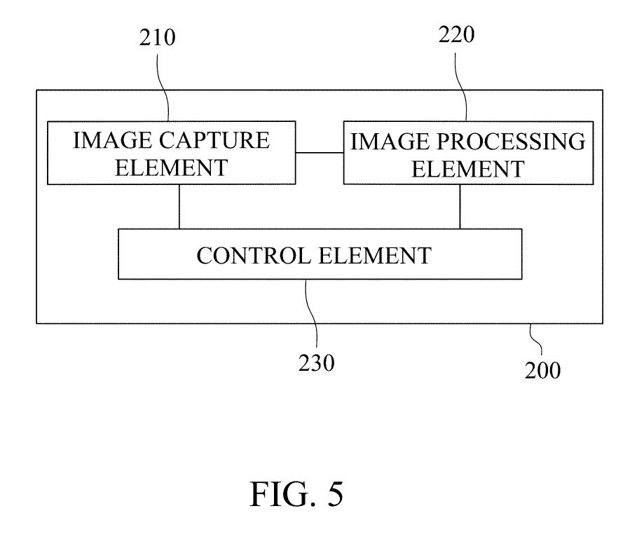

With reference to FIGS. 3 to 5, an automated optical inspection (AOI) device 200 is utilized to control the laser beam L such that the laser beam L can etch the carrier 110 along the space S in this embodiment. The AOI device 200 includes an image capture element 210, an image processing element 220 and a control element 230. The image capture element 210 and the image processing element 220 are provided to capture and process the images of the semiconductor substrate 100, respectively. The control element 230 can identify the distribution of the leads 120 on the carrier 110 according to the images of the semiconductor substrate 100 and can adjust the movement and beam size of the laser beam L according to the location of the space S and the size of the pitch D1.

The control element 230 can control the movement of the laser beam L based on the location of the space S to allow the laser beam L to move along the space S between the leads 120 to etch the carrier 110. The control element 230 also can adjust the beam size of the laser beam L according to the size of the pitch D1 to allow the beam size of the laser beam L not be larger than the pitch D1 such that the leads 120 will not be etched by the laser beam L.

Preferably, the control element 230 also can adjust the intensity and moving speed of the laser beam L to form the ditches 112 having different depths. In this embodiment, the cross section profile of each of the ditches 112 is approximately semicircular because the laser beam L has a Gaussian intensity distribution. However, a laser beam with uniform intensity can be used to etch the carrier 110 to generate approximately rectangular ditches.

In the processing method of the present invention, the laser beam L is utilized to etch the carrier 110 revealed by the leads 120 to form the ditches 112 between the leads 120. The ditches 112 can improve the fluidity of fluids coated in following-up package processes so can improve the yield of semiconductor packages. Additionally, the processing method of the present invention can be used to precisely process semiconductor substrates having super fine pitch because the laser beam L has high directivity.

While this invention has been particularly illustrated and described in detail with respect to the preferred embodiments thereof, it will be clearly understood by those skilled in the art that is not limited to the specific features shown and described and various modified and changed in form and details may be made without departing from the spirit and scope of this invention.

1. A processing method of a semiconductor substrate, the semiconductor substrate including a carrier, a plurality of leads formed on a surface of the carrier, and a space existing between adjacent leads and revealing the surface, the processing method being characterized in comprising a step of using a laser beam which passes through the space to etch the carrier so as to remove metals, photoresists, and contaminates remaining in the space and to form a plurality of ditches recessed on the surface revealed by the space.

2. The processing method in accordance with claim 1, wherein the carrier has a thickness and the ditches have a depth, the depth is smaller than or equal to one half of the thickness.

3. The processing method in accordance with claim 1, wherein the carrier has a thickness between 20 μm and 40 μm, and the ditches have a depth between 0.1 μm and 15 μm.

4. The processing method in accordance with claim 1, wherein there is a connecting interface between a later surface of each of the leads and a later wall of each of the ditches, the carrier is melted partially to generate a melted material when the carrier is etched by the laser beam, wherein the melted material is solidified on the connecting interface to form a protection layer, and the protection layer overlay on the connecting interface.

5. The processing method in accordance with claim 1, wherein an automated optical inspection device is provided to control the laser beam to etch the carrier along the space.

6. The processing method in accordance with claim 1, wherein a pitch smaller than 20 μm exists between the adjacent leads.

7. A semiconductor substrate comprising:
a carrier having a surface and a plurality of ditches; and
a plurality of leads formed on the surface of the carrier, a space exists between the adjacent leads and reveals the surface, and the ditches are recessed on the surface revealed by the space, wherein the ditches are formed by using a laser beam which passes through the space to etch the carrier.

8. The semiconductor substrate in accordance with claim 7, wherein the carrier has a thickness and the ditches have a depth, the depth is smaller than or equal to one half of the thickness.

9. The semiconductor substrate in accordance with claim 7, wherein the carrier has a thickness between 20 μm and 40 μm, and the ditches have a depth between 0.1 μm and 15 μm.

10. The semiconductor substrate in accordance with claim 7, wherein there is a connecting interface between a later surface of each of the leads and a later wall of each of the ditches, the carrier is melted partially to generate a melted material when the carrier is etched by the laser beam, wherein the melted material is solidified on the connecting interface to form a protection layer, and the protection layer overlay on the connecting interface.

11. The semiconductor substrate in accordance with claim 7, wherein an automated optical inspection device is provided to control the laser beam to etch the carrier along the space.

12. The semiconductor substrate in accordance with claim 7, wherein a pitch smaller than 20 μm exists between the adjacent leads.
